(19) United States
(12) Patent Application Publication
(10) Pub. No.: US 2009/0261478 A1
(43) Pub. Date: Oct. 22, 2009

(54) SEMICONDUCTOR DEVICE AND METHOD FOR MANUFACTURING THE SAME

(76) Inventor: Masahiro JOEI, Louvain (BE)

Correspondence Address: MCDERMOTT WILL & EMERY LLP, 600 13TH STREET, NW, WASHINGTON, DC, 20005-3096, US

(21) Appl. No.: 12/415,154

(22) Filed: Mar. 31, 2009

(30) Foreign Application Priority Data
Apr. 16, 2008 (JP) 2008-106487

(51) Int. Cl. H01L 23/48; H01L 21/60

(52) U.S. Cl. 257/774; 438/655; 257/E23.011; 257/E21.507; 257/741

(57) ABSTRACT

The present invention constitutes a semiconductor device wherein a Ni-containing metal silicide layer is formed on a semiconductor substrate and its uppermost surface is nitrided. According to this structure, a dangling bond of silicon existing in the metal silicide layer and nitrogen are bonded by nitridation of the uppermost surface of the metal silicide layer. Therefore, diffusion of oxygen into the metal silicide layer can be suppressed. As a result, electrical insulation due to oxidation of the metal silicide layer can be reduced and the contact resistance can be stabilized.

### CROSS-REFERENCE TO RELATED APPLICATION

The present application claims the benefit of Japanese Patent Application No. 2008-106487 filed Apr. 16, 2008, the subject matter of which is incorporated herein by reference.

### BACKGROUND OF THE INVENTION

1. Field of the Invention

The present invention relates to a semiconductor device and a method for manufacturing the same, and particularly relates to a contact structure of semiconductor devices including a metal silicide layer and a method for forming the same.

2. Description of the Related Art

In recent semiconductor circuits, design rules have been reduced in order to improve integration degree and to improve device characteristics. Here is explained a conventional manufacturing method of semiconductor devices with reference to FIGS. 5A to 5E.

FIGS. 5A to 5E are process cross-sectional views showing the manufacturing steps of a semiconductor device based on the conventional manufacturing method. In FIGS. 5A to 5E, FIG. 5A shows a state in which a nickel silicide layer is formed on a semiconductor substrate and an interlayer insulating film is formed on the nickel silicide layer. FIG. 5B shows a state in which a contact hole is formed in the interlayer insulating film by dry etching after formation of an etching mask on the top of the interlayer insulating film. FIG. 5C shows a state in which an etching deposit on an inner surface of the contact hole are removed by ashing and washing. FIG. 5D shows a state in which a natural oxide film formed on a surface of the nickel silicide layer is removed. FIG. 5E shows a state in which a W (tungsten) plug is formed in the contact hole.

In the conventional manufacturing steps of the semiconductor device, first, as shown in FIG. 5A, on a semiconductor substrate 51 formed with a nickel silicide layer 52, a contact etching stop layer 53 made of a silicon nitride film and an interlayer insulating film 54 made of a silicon oxide film are formed in that order from the bottom. Next, as shown in FIG. 5B, a resist pattern 55b having an opening 55a at a position for forming the contact hole is formed on the interlayer insulating film 54 by a lithographic technique. A contact hole 55 is formed in the interlayer insulating film 54 and the contact etching stop layer 53 by dry etching with the resist pattern 55b as a mask. At this time, an organic etching deposit 56 is generated by the reaction of a dry etching gas and a construction material of the interlayer insulating film 54, and the etching deposit 56 adheres to the inner surface of the contact hole 55.

Successively, as shown in FIG. 5C, the resist pattern 55b and the etching deposit 56 are removed by ashing using a plasma and a sulfuric acid-hydrogen peroxide mixture. At this time, a natural oxide film 57 comprised of a silicon oxide film and a nickel oxide film is formed in a film thickness of about 5 to 6 nm on a surface of the nickel silicide layer 52 exposed on the bottom surface of the contact hole 55. As shown in FIG. 5D, the natural oxide film 57 is removed by Ar sputter etching method or NF₃-based chemical etching method. Subsequently, as shown in FIG. 5E, a contact plug 58 comprised of embedded W and a Ti adhesion layer formed onto the bottom surface and the sidewall surface of the contact hole 55 (e.g., see Japanese Laid-Open Patent Application publication 2007-214538.).

### SUMMARY OF THE INVENTION

As described above, it has been known that the Ar sputter etching method or the NF₃-based chemical etching method is used for the natural oxide film removal step shown in FIG. 5D in the conventional method for forming a contact plug.

However, when the Ar sputter etching method is used, a probability of injecting an Ar ion into a lower part inside the contact hole 55 reduces due to a micro diameter and a high aspect ratio of the contact hole 55. Therefore, removal efficiency of the natural oxide film 57 is reduced and the removal of the natural oxide film 57 becomes difficult even if it is the natural oxide film 57 of about 5 nm. The removal amount of the natural oxide film 57 can be increased by increasing the processing time of the Ar sputter etching. However, when the processing time is increased, the removal amount of the interlayer insulating film 54 constructing the upper sidewall of the contact hole 55 is increased and a shape of the contact hole 55 also fluctuates. Namely, there is the problem that the natural oxide film 57 could not be removed within a range in which the Ar sputter etching did not exert an effect on processing shape of a periphery of the contact hole 55 and a dispersion of contact resistance is increased. Here, a specific resistance of Ni is 6.8 μΩcm, but NiO is almost an insulator.

On the other hand, when the chemical etching method with NF₃ is used, the natural oxide film 57 and the interlayer insulating film 54 made of a silicon oxide film are etched simultaneously. Since the etching is isotropic, not only a horizontal surface (top surface) of the interlayer insulating film 54 but also the sidewall of the contact hole 55 is also etched. Accordingly, when the natural oxide film 57 of 5 nm in film thickness is removed, the sidewall of the contact hole 55 is also etched to 5 nm in a transverse direction, and the diameter of the contact hole 55 increases by 10 nm. As a result, there is the problem that the natural oxide film 57 is difficult to remove while the shape and dimensions (geometry) of a micro contact hole of about 50 nm are stabilized.

The present invention is proposed in view of the above conventional circumstances and the purpose of the present invention is to provide a semiconductor device and a semiconductor device manufacturing method capable of reducing dispersion of contact resistance while stabilizing the shape dimensions of micro contact holes.

In order to resolve the above problems, the present invention adopts following technical means. A semiconductor device relating to the present invention comprises a metal silicide layer formed on a semiconductor substrate, an interlayer insulating film formed on the metal silicide layer, a contact hole reaching the metal silicide layer formed in the interlayer insulating film, a conducting material embedded in the contact hole and a nitrided metal silicide layer provided in a region within at least a given distance outward from a hole edge of a bottom surface of the contact hole in a surface portion of the metal silicide layer.

The structure is results of ashing, washing with a chemical solution and then removing an oxide film formed at the bottom surface of the contact hole in a state where the metal silicide layer with a nitrided surface portion is exposed as the bottom surface of the contact hole. For example, when the nitrided metal silicide layer is completely removed with a natural oxide film during removal of the oxide film of the bottom surface of the contact hole, the bottom surface of the contact hole is constructed with the metal silicide layer without the nitrided surface portion. When the nitrided metal silicide layer at the bottom surface of the contact hole is not completely removed, the nitrided metal silicide layer remains on the bottom surface of the contact hole. In both cases, the nitrided metal silicide layer exists at the surface portion of the metal silicide layer exposed to the bottom of the contact hole during ashing inside the contact hole, and a film thickness of the oxide film formed at the bottom surface of the contact hole is reduced in comparison with the conventional method. As a result, the removal of the oxide film can be easily accomplished, and a contact structure with low contact resistance may be stably manufactured.

On the other hand, the present invention, when viewed from another perspective, can also provide a manufacturing method of a semiconductor device. Namely, in the manufacturing method of the semiconductor device relating to the present invention, first, a metal silicide layer is formed on a semiconductor substrate. Next, a nitriding treatment for making a surface portion of the metal silicide layer into a nitrided metal silicide layer is accomplished. An interlayer insulating film is formed in an upper layer of the metal silicide layer of which the surface portion is nitrided. Then, the contact hole is formed in the interlayer insulating film. At this time, the metal silicide layer is exposed at a bottom surface of the contact hole.

The above contact hole forming step may include a step for selectively removing the interlayer insulating film by dry etching with a pattern made of a resist film formed on the interlayer insulating film as a mask. In this case, the resist film and an etching deposit generated during the dry etching are removed by using a plasma containing at least oxygen and an using oxidative solution.

In still another manufacturing method of a semiconductor device relating to the present invention, first, a metal silicide layer is formed on a semiconductor substrate. Next, an interlayer insulating film is formed in an upper layer of the metal silicide layer. A contact hole is formed in the interlayer insulating film. At this time, the metal silicide layer is exposed at the bottom surface of the contact hole. Then, a nitriding treatment for making a surface portion of the metal silicide layer exposed at the bottom surface of the contact hole into a nitrided metal silicide layer is accomplished.

For example, the above contact hole forming step may include a step for selectively removing the interlayer insulating film by dry etching with a pattern made of a resist film formed on the interlayer insulating film as a mask. In this case, the nitriding treatment for making the surface portion of the metal silicide layer into the nitrided metal silicide layer is accomplished and then the resist film and an etching deposit generated during the dry etching is removed by using a plasma at least containing oxygen and using oxidative solution.

The above manufacturing method may further comprise a step of performing sputter etching onto the bottom surface of the contact hole after the removing step and a step of embedding a conducting material into the contact hole performed the sputter etching.

The above semiconductor device and manufacturing method of the semiconductor device are suitable for a case in which a metal constructing the metal silicide layer contains nickel. A nitrogen concentration in the nitrided metal silicide layer is preferably equal to or greater than 1E18 atoms/cm³ to equal to or less than 1E21 atoms/cm³.

For example, the nitriding treatment for making the surface portion of the metal silicide layer into the nitrided metal silicide layer can be realized by a treatment for exposing the metal silicide layer to a nitrogen plasma, a treatment for injecting nitrogen ions into the metal silicide layer or a treatment for heating the metal silicide layer in a nitrogen atmosphere or the like.

In the present invention, nitrogen is bonded to a dangling bond of silicon existing in the metal silicide layer due to nitridation of an uppermost surface of the metal silicide layer containing nickel or the like on the semiconductor substrate, suppressing a diffusion of oxygen into the metal silicide layer. As a result, oxidation of the metal silicide layer can be inhibited, reducing the increase in contact resistance caused by the oxidation. Accordingly, a micro contact structure can be stably formed without increasing the contact resistance.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic diagram showing a cross-sectional structure of a semiconductor device relating to an embodiment of the present invention.

FIGS. 2A to 2G are process cross-sectional views showing manufacturing processes of a semiconductor device relating to an embodiment of the present invention.

FIG. 3 is a graph showing the results of elemental analysis from a surface of nickel silicide to a semiconductor substrate relating to an embodiment of the present invention.

FIG. 4 is a graph for comparing dispersions of contact resistance of an embodiment of the present invention and of a conventional method.

FIGS. 5A to 5E are process cross-sectional views showing manufacturing processes of a conventional semiconductor device.

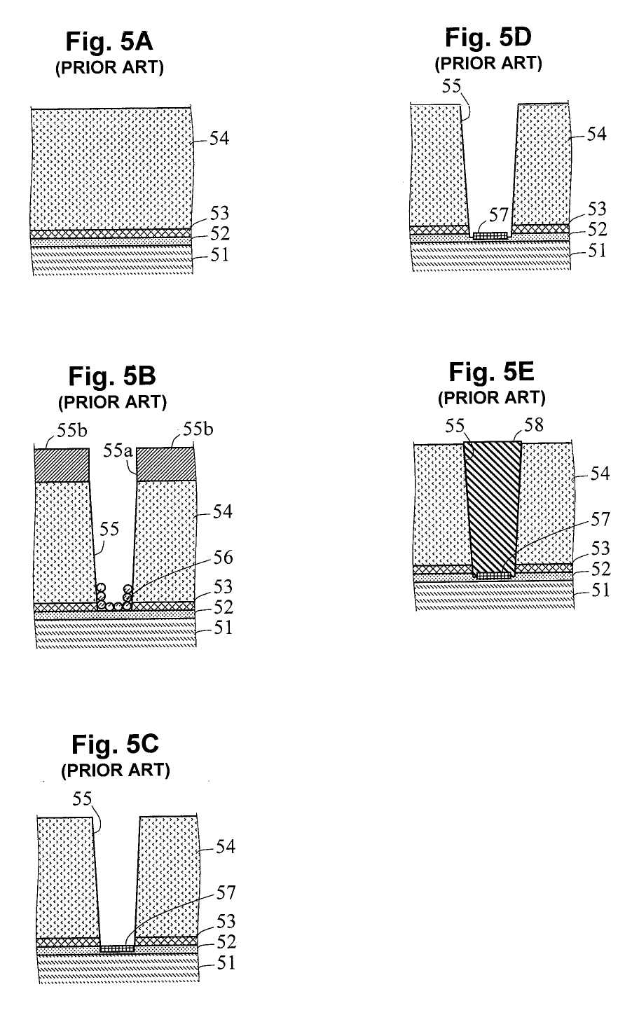

### DETAILED DESCRIPTION OF PREFERRED EMBODIMENTS

A semiconductor device relating to an embodiment of the present invention is described hereafter with reference to the drawings. In the following embodiments, the present invention is embodied as a semiconductor device having a metal silicide layer which comprises nickel silicide.

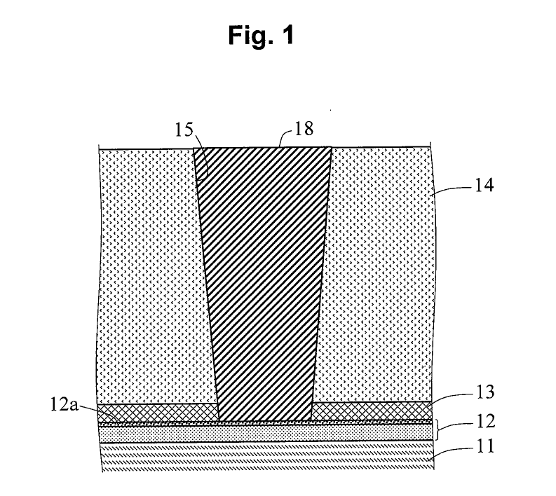

FIG. 1 is a schematic diagram showing a cross-sectional view of a contact structure of a semiconductor device in an embodiment of the present invention. As shown in FIG. 1, in the semiconductor device of this embodiment, a nickel silicide layer 12 is formed in a film thickness of about 20 nm on a semiconductor substrate (silicon substrate) 11. Nitrogen is bonded to Si in the nickel silicide layer 12 to terminate a dangling bond of a silicon atom in an uppermost surface portion 12a of the nickel silicide layer 12. A contact etching stop layer 13 made of a silicon nitride film and an interlayer insulating film 14 made of a silicon oxide film are formed on the nickel silicide layer 12 having the nitrided uppermost surface portion 12a (hereafter, referred to as the nitrided nickel silicide layer 12a) of.

In the interlayer insulation film 14, a contact hole 15 being an opening reaching to the surface of the nickel silicide layer 12 is formed. Inside contact hole 15, a contact plug 18 is formed in order to have electrical connection with the nickel silicide layer 12. The contact plug 18 comprises an adhesion layer and embedded W (tungsten) by CVD (Chemical Vapor Deposition) method, the adhesion layer consisting of a multilayer film of Ti and TiN deposited.

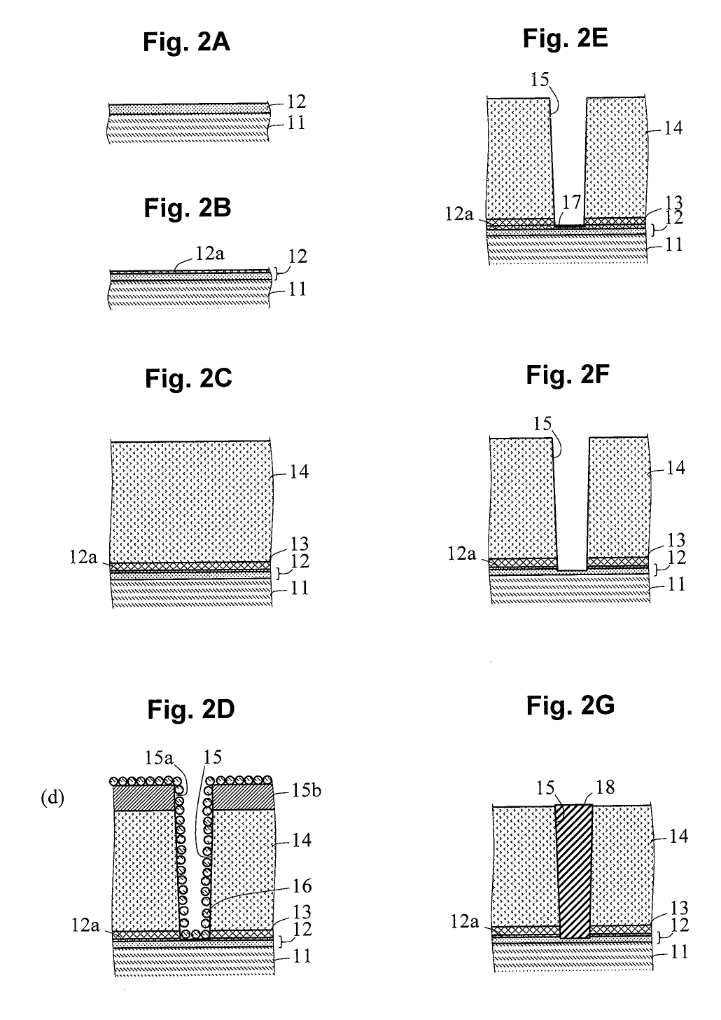

Next, a manufacturing method of the semiconductor device having the contact hole 15 shown in FIG. 1 is described with reference to the drawings. FIGS. 2A to 2G are process cross-sectional views showing the manufacturing steps of the semiconductor device relating to the present embodiment. In FIGS. 2A to 2G, FIG. 2A shows a step forming a nickel silicide layer on a semiconductor substrate. FIG. 2B shows a step nitriding a surface portion of the nickel silicide layer with a nitrogen plasma. FIG. 2C shows a step forming an interlayer insulating film in an upper layer of the nitrided nickel silicide layer. FIG. 2D shows a step forming a contact hole by dry etching after patterning of an etching mask comprised of a resist film by lithography. FIG. 2E shows a step removing the resist film or the like by ashing and an etching deposit inside the contact hole by washing with a chemical solution. FIG. 2F shows a step removing a natural oxide film formed at a surface of the nickel silicide layer by Ar sputter etching.

FIG. 2G shows a step forming a W plug in the contact hole.

In the manufacturing method of a semiconductor device relating to this embodiment, first, as shown in FIG. 2A, the nickel silicide layer 12 is formed on the semiconductor substrate (silicon substrate) 11. For example, the nickel silicide layer 12 is formed at a surface of an impurity region formed in a surface portion of the semiconductor substrate 11. As is well-known, the nickel silicide layer 12 can be formed by depositing a nickel film on the semiconductor substrate 11 and conducting a predetermined heat treatment.

Then, as shown in FIG. 2B, a nitrogen plasma treatment is accomplished onto the surface of nickel silicide layer 12. The surface of the nickel silicide layer 12 is nitrided by the nitrogen plasma treatment, and the nitrided nickel silicide layer 12a is formed in the surface portion of the nickel silicide layer 12. For example, the nitridation treatment (nitrogen plasma treatment) can be accomplished by a plasma treatment apparatus having parallel-plate type high-frequency power impressing electrodes. As treatment conditions, a high-frequency power for plasma excitation: frequency 13.56 kHz, RF power 1,000 W, flow rate of N₂ introduced into a treatment chamber: 500 sccm (standard cc per minute), pressure in the treatment chamber: 5 Pa, semiconductor substrate temperature or electrode temperature on a side for arranging the substrate: 20° C., and nitridation time for exposing the nickel silicide layer 12 to nitrogen plasma: 30 sec can be adopted. The frequency of the high-frequency power for plasma excitation is not limited to 13.56 kHz, and the same effect can also be achieved by using any frequency, such as a microwave power source of 2.45 GHz or the like. The substrate temperature is not specifically limited, and the surface of nickel silicide layer can be amply nitrided if it is 0 to 100° C. If a mean free path of nitrogen ions contained in the nitrogen plasma is large, the nitrogen ions are efficiently accelerated by an electric field and driven deeply into the nickel silicide layer, so that a plasma treatment at a comparatively low pressure (0.1 to 200 Pa) is desirable.

Successively, as shown in FIG. 2C, the contact etching stop layer 13 made of a silicon nitride film and the interlayer insulating film 14 made of a silicon oxide film are formed in that order from the bottom in an upper layer of the nitrided nickel silicide layer 12a. For example, a plasma CVD method can be used for deposition of the silicon nitride film. As treatment conditions in this case, process gases introduced into a treatment chamber: SiH₄ flow rate 50 sccm, NH₃ flow rate 500 sccm and N₂ flow rate 500 sccm, RF power: 100 W, pressure in the treatment chamber: 1,000 Pa, and semiconductor substrate temperature: 300° C. can be adopted. Also, a thermal CVD method can be used for deposition of the silicon oxide film. As treatment conditions in this case, for example, process gases introduced into a treatment chamber: TESO (Tetraethyl Orthosilicate) flow rate 2,500 mg/min and O₃ flow rate 10,000 sccm, pressure in the treatment chamber: 600 Torr (80 kPa), and semiconductor substrate temperature: 400° C. can be adopted.

Successively, as shown in FIG. 2D, a resist pattern 15b having an opening 15a is formed by applying lithographic technique, then the interlayer insulating film 14 and the contact etching stop layer 13 are etched by dry etching with the resist pattern 15b as a mask to form the contact hole 15. At this time, the surface of the nitrided nickel silicide layer 12a is exposed on the bottom surface of the contact hole 15. For example, the contact hole 15 can be formed by using a parallel-plate type plasma etching apparatus. As dry etching conditions in this case, RF power: 1,000 W, pressure in a treatment chamber: 5 Pa, flow rates of C₅F₈ and O₂ introduced into the treatment chamber: 15 sccm can be adopted. At this time, etching deposits 16, which is an organic fluorocarbon, is generated, and the etching deposits 16 adhere to and are deposited onto the contact hole 15.

Next, as shown in FIG. 2E, the resist pattern 15b and the etching deposits 16 are removed by ashing treatment with an oxygen plasma or an oxygen-containing plasma and further with a high-temperature sulfuric acid-hydrogen peroxide mixture. At this time, it becomes a state in which a very small quantity (about from 1 to 2 nm) of a natural oxide film 17 comprised of a silicon oxide film and a nickel oxide film is formed on the nitrided nickel silicide layer 12a by the removal step comprising the ashing treatment and the mixture treatment (oxidative solution).

Next, as shown in FIG. 2F, the natural oxide film 17 is removed by an Ar sputter etching method. At this time, only an extremely small quantity (about from 1 to 2 nm) at the surface of the nickel silicide layer 12 (the surface of the nitrided nickel silicide layer 12a) grows up in this embodiment. Therefore it is also possible to fully remove the natural oxide film 17 by the Ar sputter etching method within a range not affecting the processing shape of a periphery of the contact hole 15. When the natural oxide film 17 is removed, the nitrided nickel silicide layer 12a may also be completely removed, depending on the film thickness of the nitrided nickel silicide layer 12a. A part of the nitrided nickel silicide layer 12a may also remain. The contact resistance does not vary because the nitrided nickel silicide layer 12a has resistance equal to the nickel silicide layer 12.

Next, as shown in FIG. 2G, on the bottom surface and the sidewall surface of the contact hole 15, a multilayer film comprising Ti and TiN is formed as an adhesion layer, and a W film is embedded in the contact hole 15 by the CVD method, and then, the contact plug 18 is formed. At this time, each treatment can be continuously accomplished by maintaining an environment in at least a depressurized state near to vacuum without being released from the Ar sputter etching step to the W formation step for the contact plug.

According to this embodiment, the oxidation of the surface of nickel silicide layer 12 can be inhibited as compared with the conventional method. Accordingly, an ohmic contact can be easily obtained because the silicon oxide film and the nickel oxide film, which are insulators, do not remain between the nickel silicide layer 12 and the contact plug 18 immediately before the formation of the Ti/TiN multilayer film.

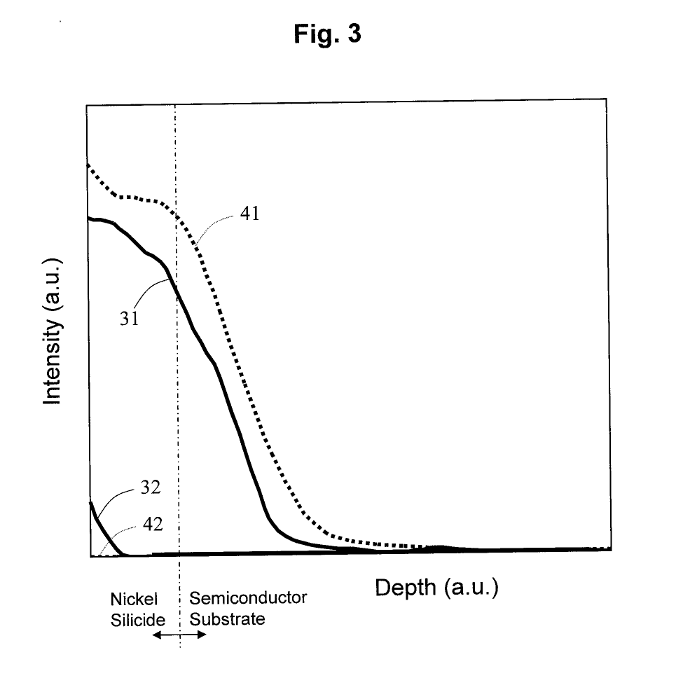

The nitrided nickel silicide layer 12a is further described hereafter. FIG. 3 is a graph showing results of elemental analysis in a depth direction from the uppermost surface of the nickel silicide layer 12 to the semiconductor substrate 11. FIG. 3 shows profiles of oxygen and nitrogen. In FIG. 3, solid lines 31, 32 are results corresponding to the structure of this embodiment, and broken lines 41, 42 are results corresponding to the conventional structure. The solid line 31 and the broken line 41 are the distribution of oxygen, the solid line 32 and the broken line 42 are the distribution of nitrogen. Samples used in the elemental analysis are prepared through the contact hole formation step, the resist film removal step and the etching deposit removal step as described above, the adhesion layer and the W plug are not formed.

As understood from FIG. 3, in the conventional structure, many peaks of oxygen exist on the surface of nickel silicide layer and peaks of nitrogen do not exist on the surface. On the other hand, in the structure of this embodiment, nitrogen exists on the surface of the nickel silicide layer 12 and peaks of oxygen on the surface are reduced. Namely, the oxidation of the nickel silicide layer 12 can be inhibited in the structure of this embodiment.

It is considered that the dangling bond of silicon atom existing in the nickel silicide layer 12 and nitrogen are bonded to terminate the dangling bond, therefore diffusion of oxygen into the nickel silicide layer 12 is prevented and consequently oxidation of the nickel silicide layer 12 is inhibited. From experimental results obtained so far, it is desirable that the film thickness of nitrided nickel silicide layer 12a be within a few atomic layer, and that a concentration of N atoms in the nitrided nickel silicide layer 12a be from 1E18 atoms/cm³ to 1E21 atoms/cm³. A contact resistance fully satisfying characteristics of a high-speed CMOS semiconductor integrated circuit can be stably obtained in a contact hole having a diameter of 40 nm or more by making the nitrogen concentration into this range.

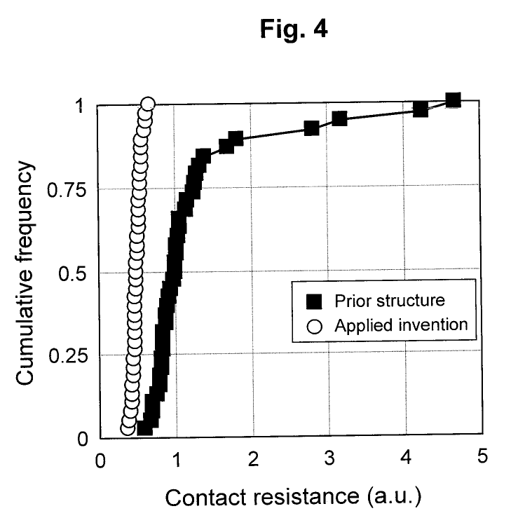

FIG. 4 is a graph for comparing dispersions of contact resistance in the structure of this embodiment and the conventional structure. In FIG. 4, the horizontal axis corresponds to the contact resistance, and the vertical axis corresponds to a cumulative frequency. In FIG. 4, data represented by circles comprise the contact resistance in the structure of this embodiment, and data represented by rectangles comprise the contact resistance in the conventional structure.

As understood from FIG. 4, in the conventional structure, the dispersion of contact resistance on a high-resistance side is large. In contrast to this, in the structure of this embodiment, the contact resistance is reduced by about 85% as compared with the conventional structure at a contact resistance value where the cumulative frequency is 1; and by about 50% as compared with the conventional structure at a contact resistance value where the cumulative frequency is 0.5 (center value). Accordingly, it is understood that the contact resistance can be stably realized in a low resistance range according to the structure of this embodiment.

As described above, according to the present invention, the uppermost surface of the nickel silicide layer is nitrided and the oxidation of the nickel silicide layer can be inhibited. Accordingly, a low-resistance ohmic contact can be easily obtained because remaining the silicon oxide film and the nickel oxide film, which are insulators, interposed between the nickel silicide layer and the adhesion layer of the contact plug can be prevented.

The present invention is not limited to above-mentioned embodiment, and various modifications and applications are possible within a range where there is no deviation from the technical concept of the present invention. In the above description, for example, the nitridation of the nickel silicide layer can be realized by conducting the nitrogen plasma treatment immediately after the formation of nickel silicide layer, instead, the same results can also be obtained by conducting the nitrogen plasma treatment for the nickel silicide layer before the removal of resist film and etching deposit by ashing with the oxygen plasma and using the oxidative solution, such as a sulfuric acid-hydrogen peroxide mixture. In this case, nitrogen diffuses slightly outward in a transverse direction from a hole edge of the bottom surface of the contact hole in the nickel silicide layer. Accordingly, the nitrided nickel silicide layer 12a exists in a region within a given distance outward from the hole edge of the bottom surface of the contact hole in a finished semiconductor device. Particularly, when the nitrided nickel silicide layer exposed on the bottom surface of the contact hole is completely removed by etching, the nitrided nickel silicide layer 12a exists only in the region within the given distance outward from the hole edge of the bottom surface of the contact hole.

Moreover, the nitridation of the surface of the nickel silicide layer is not limited to the nitridation using the plasma treatment method, the same results are also obtained in ion implantation using nitrogen ions or nitrogen-containing ions, or in heat treatment in nitrogen atmosphere or a nitrogen-containing atmosphere. In addition, a metal constructing the metal silicide layer is not limited to nickel and may also be another metal.

The present invention has an effect capable of the stably formation of a low-resistance contact structure on a metal silicide layer containing nickel or the like and is useful as a semiconductor device and a manufacturing method for the same.

What is claimed is:

1. A semiconductor device, comprising:
a metal silicide layer formed on a semiconductor substrate;
an interlayer insulating film formed on the metal silicide layer;
a contact hole reaching the metal silicide layer formed in the interlayer insulating film and;
a conducting material embedded into the contact hole; and
a nitrided metal silicide layer provided in a region within at least a given distance outward from a hole edge of a bottom surface of the contact hole in a surface portion of the metal silicide layer.

2. A semiconductor device according to claim 1, wherein a surface portion of the metal silicide layer inside the hole edge of the bottom surface of the contact hole is provided with the nitrided metal silicide layer.

3. A semiconductor device according to claim 1, wherein a metal constructing the metal silicide layer contains nickel.

4. The semiconductor device according to claim 1, wherein a nitrogen concentration in the nitrided metal silicide layer is from 1E18 atoms/cm³ to 1E21 atoms/cm³.

5. A manufacturing method of a semiconductor device, comprising the steps of:
forming a metal silicide layer on a semiconductor substrate;
nitriding a surface portion of the metal silicide layer;
forming an interlayer insulation film in an upper layer of the metal silicide layer of which the surface portion is nitrided; and
forming a contact hole in the interlayer insulation film so as to expose the metal silicide layer at a bottom surface of the contact hole.

6. A manufacturing method of a semiconductor device according to claim 5, wherein the contact hole forming step includes a step of removing the interlayer insulation film by dry etching with a pattern made of a resist film formed on the interlayer insulation film as a mask and further comprising a step of:
removing the resist film and an etching deposit generated during the dry etching by using a plasma containing at least oxygen and using an oxidative solution.

7. A manufacturing method of a semiconductor device, comprising the steps of:
forming a metal silicide layer on a semiconductor substrate;
forming an interlayer insulation film in an upper layer of the metal silicide layer;
forming a contact hole in the interlayer insulation film so as to expose the metal silicide layer at a bottom surface of the contact hole; and
nitriding a surface portion of the metal silicide layer exposed at the bottom surface of the contact hole.

8. A manufacturing method of a semiconductor device according to claim 7, wherein the contact hole forming step includes a step of removing the interlayer insulation film by dry etching with a pattern made of a resist film formed on the interlayer insulation film as a mask and further comprising a step of:
removing the resist film and an etching deposit generated during the dry etching by using a plasma containing at least oxygen and using an oxidative solution after the nitriding step.

9. A manufacturing method of a semiconductor device according to claim 6, further comprising the steps of:
performing sputter etching onto the bottom surface of the contact hole after the removing step; and
embedding a conductive material into the contact hole performed the sputter etching.

10. A manufacturing method of a semiconductor device according to claim 8, further comprising the steps of:
performing sputter etching onto the bottom surface of the contact hole after the removing step; and
embedding a conductive material in the contact hole performed the sputter etching.

11. A manufacturing method of a semiconductor device according to claim 5, wherein a metal constructing the metal silicide layer contains nickel.

12. A manufacturing method of a semiconductor device according to claim 7, wherein a metal constructing the metal silicide layer contains nickel.

13. A manufacturing method of a semiconductor device according to claim 5, wherein, in the nitriding step, a nitridation of the metal silicide layer is performed by exposing the metal silicide layer to a nitrogen plasma.

14. A manufacturing method of a semiconductor device according to claim 7, wherein, in the nitriding step, a nitridation of the metal silicide layer is performed by exposing the metal silicide layer to a nitrogen plasma.

15. A manufacturing method of a semiconductor device according to claim 5, wherein, in the nitriding step, a nitridation of the metal silicide layer is performed by ion-injecting nitrogen ions into the metal silicide layer.

16. A manufacturing method of a semiconductor device according to claim 7, wherein, in the nitriding step, a nitridation of the metal silicide layer is performed by ion-injecting nitrogen ions into the metal silicide layer.

17. A manufacturing method of a semiconductor device according to claim 5, wherein, in the nitriding step, a nitridation of the metal silicide layer is performed by heating the metal silicide layer in nitrogen atmosphere.

18. A manufacturing method of a semiconductor device according to claim 7, wherein, in the nitriding step, a nitridation of the metal silicide layer is performed by heating the metal silicide layer in nitrogen atmosphere.
